(19) United States
(12) Patent Application Publication
(10) Pub. No.: US 2025/0331333 A1
(43) Pub. Date: Oct. 23, 2025

(54) MICRO LIGHT-EMITTING CHIP, MICRO LIGHT-EMITTING CHIP STRUCTURE AND DISPLAY PANEL

(71) Applicant: PlayNitride Display Co., Ltd., MiaoLi County (TW)

(72) Inventors: Yi-Ru Huang, MiaoLi County (TW); Chi-Hao Cheng, MiaoLi County (TW); Ching-Liang Lin, MiaoLi County (TW)

(73) Assignee: PlayNitride Display Co., Ltd., MiaoLi County (TW)

(21) Appl. No.: 18/961,293

(22) Filed: Nov. 26, 2024

Related U.S. Application Data
(60) Provisional application No. 63/637,676, filed on Apr. 23, 2024.

(30) Foreign Application Priority Data
Aug. 14, 2024 (TW) 113130428

(51) Int. Cl. H01L 33/08; H01L 25/075; H01L 33/22; H01L 33/38; H01L 33/44; H01L 33/46; H01L 33/58; H01L 33/62

(52) U.S. Cl. CPC H10H 20/813; H01L 25/0753; H10H 20/82; H10H 20/8316; H10H 20/84; H10H 20/841; H10H 20/855; H10H 20/857

(57) ABSTRACT

A micro light-emitting chip includes two sub-chips, an insulating structure, a conductive element, and a protection element. The insulating structure is disposed between the two sub-chips, so that the two sub-chips are electrically insulated from each other at the insulating structure. The conductive element is electrically connected to the two sub-chips. The protection element is an insulating layer and is configured on outer surfaces of the two sub-chips and the insulating structure. The protection element has a first surface and a second surface arranged along a thickness direction of the two sub-chips, and the two sub-chips and the conductive element are located between the first surface and the second surface. A micro light-emitting chip structure and a display panel are also proposed.

### CROSS-REFERENCE TO RELATED APPLICATION

This application claims the priority benefit of U.S. provisional application Ser. No. 63/637,676, filed on Apr. 23, 2024, and Taiwan application serial no. 113130428, filed on Aug. 14, 2024. The entirety of each of the above-mentioned patent applications is hereby incorporated by reference herein and made a part of this specification.

### BACKGROUND

### Technical Field

The disclosure relates to a light-emitting element, a substrate structure, and a display device, and particularly relates to a micro light-emitting chip, a micro light-emitting chip structure, and a display panel.

### Description of Related Art

A micro light-emitting diode panel includes an active component substrate and a micro light-emitting diode (micro LED) on the active component substrate, and is electrically connected to a drive circuit layer in the active component substrate. The micro LED panel has become the focus of research and development by major manufacturers due to having the advantages of high brightness, high resolution, and high contrast.

However, achieving higher brightness requires the driving thin-film transistors (TFTs) to consume more power during display. Therefore, a solution is needed to address the high power consumption issue of traditional micro-LED displays.

### SUMMARY

The disclosure provides a micro light-emitting chip with good device reliability and structural strength.

The disclosure provides a micro light-emitting chip structure that has better yield when transposing a micro light-emitting chip.

The disclosure provides a display panel, which has the advantages of high brightness, low power consumption, and good structural strength.

According to an embodiment of the disclosure, a micro light-emitting chip is provided, which includes two separate sub-chips, an insulating structure, a conductive element, and a protection element. The insulating structure is disposed between the two sub-chips, so that the two sub-chips are electrically insulated from each other at the insulating structure. The conductive element is electrically connected to the two sub-chips. The protection element is an insulating layer and is configured on outer surfaces of the two sub-chips and the insulating structure. The protection element has a first surface and a second surface arranged along a thickness direction of the two sub-chips, and the two sub-chips and the conductive element are located between the first surface and the second surface.

According to an embodiment of the disclosure, a micro light-emitting chip structure is provided, including a temporary carrier, a fixing element, and a plurality of above-mentioned micro light-emitting chips. The plurality of above-mentioned micro light-emitting chips are fixed on the temporary carrier through the fixing element. The plurality of micro light-emitting chips are electrically insulated from the temporary carrier.

According to an embodiment of the disclosure, a display panel is provided, including a circuit substrate, a plurality of above-mentioned micro light-emitting chips, and two electrodes. The circuit substrate has a plurality of pixel circuits, and the two electrodes are electrically connected to one and the other of the two sub-chips respectively, and one of the two electrodes is electrically bonded to one of the pixel circuits.

Based on the above, the micro light-emitting chip of the embodiment of the disclosure includes two or more than two sub-chips, and the plurality of sub-chips are formed into a series-connected structure through the conductive element. In this way, the series-connected structure may distribute high voltage to the plurality of sub-chips, so that each sub-chip may be adapted and adjusted to a suitable operating voltage, thereby avoiding the power consumption of the transformer circuit and also having the advantages of the high brightness, high power, and high extraction rate. Not only that, by respectively disposing the insulating structure between two adjacent sub-chips, and disposing the protection element on the upper and lower surfaces of the two sub-chips in the thickness direction, the structural strength of the micro light-emitting chips can not only be improved, but the accuracy or uniformity requirements of the transfer process (such as mass transfer) can also be reduced, thereby resulting in better transfer yields. In addition, the display panel that uses the micro light-emitting chips as display pixels can also have the advantages of high brightness, low power consumption, and good structural strength, further enhancing product competitiveness.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic cross-sectional view of a micro light-emitting chip according to an embodiment of the disclosure.

FIG. 2 is a schematic cross-sectional view of a micro light-emitting chip according to an embodiment of the disclosure.

FIG. 3 is a schematic cross-sectional view of a micro light-emitting chip according to an embodiment of the disclosure.

FIG. 4 is a schematic cross-sectional view of a micro light-emitting chip according to an embodiment of the disclosure and a modified embodiment thereof.

FIG. 5 is a schematic cross-sectional view of a micro light-emitting chip according to an embodiment of the disclosure and a modified embodiment thereof.

FIG. 6A is a schematic cross-sectional view of a micro light-emitting chip according to an embodiment of the disclosure.

FIG. 6B is a schematic cross-sectional view of a micro light-emitting chip according to an embodiment of the disclosure.

FIG. 7 is a schematic cross-sectional view of a micro light-emitting chip according to an embodiment of the disclosure and a modified embodiment thereof.

FIG. 8A is a schematic cross-sectional view of a micro light-emitting chip according to an embodiment of the disclosure.

FIG. 8B is a schematic structural view of different embodiments of the optical structure of FIG. 8A.

FIG. 9 is a schematic cross-sectional view of a micro light-emitting chip according to an embodiment of the disclosure and a modified embodiment thereof.

FIG. 10A to FIG. 10C are schematic views of a manufacturing process of a micro light-emitting chip according to an embodiment of the disclosure.

FIG. 11 is a schematic cross-sectional view of a micro light-emitting chip structure according to an embodiment of the disclosure.

FIG. 12 is a schematic cross-sectional view of a display panel according to an embodiment of the disclosure.

FIG. 13 is a schematic cross-sectional view of a display panel according to an embodiment of the disclosure.

FIG. 14 is a schematic cross-sectional view of a display panel according to an embodiment of the disclosure.

### DESCRIPTION OF THE EMBODIMENTS

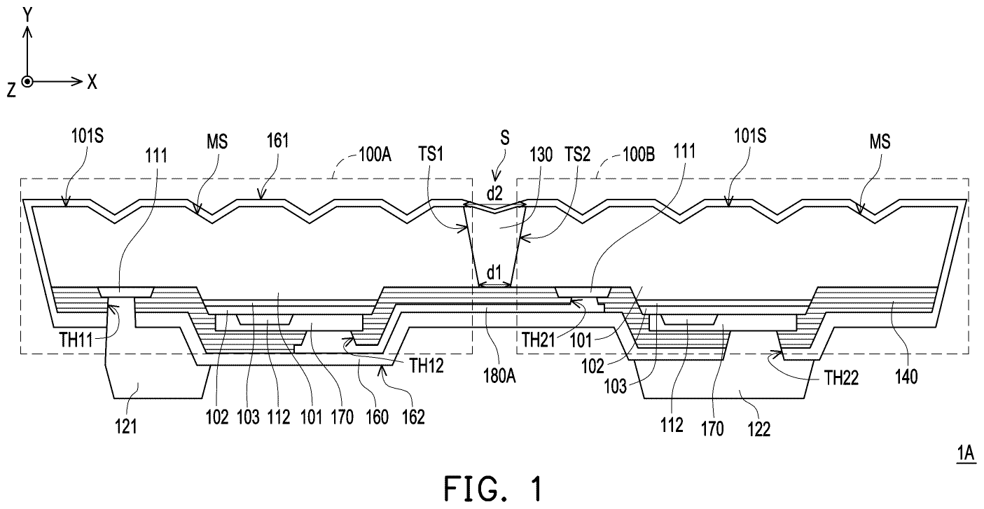

In the embodiments of FIG. 1 to FIG. 14, the same or similar elements will adopt the same or similar reference numerals, and redundant descriptions will be omitted. In addition, features in different embodiments may be combined in the case of no conflict, and simple equivalent changes and modifications made in accordance with the specification, or the claims are still within the scope covered by the patent.

FIG. 1 is a schematic cross-sectional view of a micro light-emitting chip according to an embodiment of the disclosure. Referring to FIG. 1, a micro light-emitting chip 1A includes two first sub-chip 100A and second sub-chip 100B, a first electrode 121, a second electrode 122, an insulating structure 130, a first conductive element 180A, and a protection element 160. The first sub-chip 100A and the second sub-chip 100B are, for example, micro light-emitting diodes (micro LED), mini LEDs, or light-emitting diodes of other sizes, and the disclosure is not limited thereto. Preferably, the embodiment uses the micro light-emitting diodes.

On the other hand, the light emitted by the first sub-chip 100A and the second sub-chip 100B may have substantially the same wavelength range. For example, the first sub-chip 100A and the second sub-chip 100B may both be red light-emitting diodes, green light-emitting diodes, blue light-emitting diodes, or ultraviolet light-emitting diodes. On the other hand, the micro light-emitting chip 1A of the embodiment is a flip-chip type light-emitting diode. For example, the first electrode 121 and the second electrode 122 located on the same side of the epitaxial structure of the micro light-emitting chip 1A are aligned with the corresponding pads on the pixel circuit (described later), and are bonded to each other using the commonly known surface-mount technology (SMT), such that electrical connection between the micro light-emitting chip 1A and the pixel circuit is achieved. However, the disclosure is not limited thereto.

Each of the first sub-chip 100A and the second sub-chip 100B may include a first semiconductor layer 101, a second semiconductor layer 102, and a light-emitting layer 103 that are sequentially epitaxially formed in a direction Y. The first semiconductor layer 101 may be composed of a Group III-V or a Group II-VI compound semiconductor, and may be a P-type doped semiconductor material layer. The first semiconductor layer 101 may be, for example, gallium nitride (GaN), aluminum gallium nitride (AlGaN), indium gallium nitride (InGaN), indium aluminum gallium nitride InAlGaN, etc., or may be selected from materials such as aluminum gallium arsenide (AlGaAs), gallium phosphide (GaP), gallium arsenide (GaAs), gallium arsenide phosphide (GaAsP), and aluminum gallium indium phosphide (AlGaInP). In addition, the elements doped into the first semiconductor layer 101 may be, for example, Mg, Zn, Ca, Sr, and Ba. Of course, the disclosure is not limited thereto. The first semiconductor layer 101 may be an N-type doped semiconductor material layer, and the doped elements may be Si, Ge, Sn, Se, and Te. An upper surface 101S of the first semiconductor layer 101 is a light emitting surface. In order to improve the light-emitting efficiency of the first sub-chip 100A and/or the second sub-chip 100B, in some embodiments, a roughening process may be performed on the upper surface 101S of the first semiconductor layer 101 to form a microstructure MS (for example, red LED materials, such as gallium phosphide (GaP) and aluminum gallium indium phosphide (AlGaInP)). In some alternative embodiments, the upper surface 101S may also be a microstructure MS (for example, blue LED materials, such as gallium nitride (GaN) and indium gallium nitride (InGaN)) made through a patterned sapphire substrate (PSS).

The light-emitting layer 103 is provided between the first semiconductor layer 101 and the second semiconductor layer 102. The light-emitting layer 103 provides an area that provides light radiation for recombination of electrons and holes. Different materials may be selected according to different light-emitting wavelengths. By adjusting the composition ratio of the semiconductor materials in the light-emitting layer 103, light of different wavelengths may be radiated. The light-emitting layer 103 may be a periodic structure of a single quantum well or a multiple quantum well (MQW). In order to improve the light-emitting efficiency of the light-emitting layer 103, this may be achieved by changing the material of the quantum well, the number of pairs of the quantum wells, and the layer number, thickness and/or other characteristics of the quantum well in the light-emitting layer 103, and the disclosure is not limited thereto.

The second semiconductor layer 102 is formed on the light-emitting layer 103 and may be composed of a Group III-V or a Group II-VI compound semiconductor, and may be an N-type doped semiconductor material layer. The second semiconductor layer 102 may be selected from materials such as AlGaAs, GaP, GaAs, GaAsP or GaInP. In addition, the elements doped into the second semiconductor layer 102 may be, for example, Si, Ge, Sn, Se, and Te. Of course, the disclosure is not limited thereto. The second semiconductor layer 102 may be a P-type doped semiconductor material layer, and the doped elements may be Mg, Zn, Ca, Sr, and Ba. When the first semiconductor layer 101 is a P-type semiconductor layer, the second semiconductor layer 102 is an N-type semiconductor layer. Conversely, when the first semiconductor layer 101 is an N-type semiconductor layer, the second semiconductor layer 102 is a P-type semiconductor layer.

The first electrode 121 and the second electrode 122 may be aluminum (Al), gold (Au), silver (Ag), copper (Cu), germanium gold (GeAu), or other metals or alloys suitable for producing ohmic contact with P-type semiconductors and N-type semiconductors, and may be materials suitable for connection with the metal bonding pads (described later) and the weld metal of the pixel circuit, but the disclosure is not limited thereto.

The first electrode 121 may be electrically connected to the first semiconductor layer 101 of the first sub-chip 100A via a through hole TH11, and the second electrode 122 may be electrically connected to the second semiconductor layer 102 of the second sub-chip 100B via a through hole TH22. In addition, the first conductive element 180A may be further electrically connected to the first sub-chip 100A and the second sub-chip 100B, so that the first sub-chip 100A and the second sub-chip 100B are connected in series with each other. For example, the first conductive element 180A may extend in a direction X and may be disposed on the same side of the first sub-chip 100A and the second sub-chip 100B. Two ends of the first conductive element 180A may be electrically connected to the second semiconductor layer 102 of the first sub-chip 100A and the first semiconductor layer 101 of the second sub-chip 100B respectively. The first conductive element 180A may be a metallic material, such as copper, silver, molybdenum, titanium or an alloy thereof, and may also be a transparent conductive material, such as indium tin oxide (ITO) or indium gallium zinc oxide (ITZO), and the disclosure is not limited thereto.

Accordingly, when the micro light-emitting chip 1A is enabled, the first electrode 121 may be selectively provided with a high potential, and the second electrode 122 may be selectively provided with a low potential or ground potential. Due to the potential difference generated between the first electrode 121 and the second electrode 122, the current may sequentially pass from the first electrode 121 through the first semiconductor layer 101, the light-emitting layer 103, and the second semiconductor layer 102 of the first sub-chip 100A to the first conductive element 180A, and then to the first semiconductor layer 101, the light-emitting layer 103, the second semiconductor layer 102 of the second sub-chip 100B and the second electrode 122, causing both the first sub-chip 100A and the second sub-chip 100B to emit light.

Through the above, the series-connected structure of the micro light-emitting chip 1A makes it easy to adjust the number of sub-chips to adjust the divided voltage of each sub-chip, so that each sub-chip may be provided with corresponding operating voltage accordingly (for example, the operating voltage of red LED is 1.6 volts to 2.0 volts, and the operating voltage of blue LED is 3.0 volts to 3.4 volts). When the micro light-emitting chip 1A is used in different displays, the micro light-emitting chip 1A may provide different colors of light at the same voltage, thereby reducing power consumption and simplifying the function of the circuit. On the other hand, the micro light-emitting chip 1A may also have the advantages of the high voltage diode, such as high brightness, high power, and high extraction rate.

It is worth mentioning that the insulating structure 130 is disposed between the first sub-chip 100A and the second sub-chip 100B, so that the first sub-chip 100A and the second sub-chip 100B are electrically insulated from each other at the insulating structure 130. For example, the insulating structure 130 may be directly manufactured on the structure of the micro light-emitting chip 1A. That is to say, the insulating structure 130 may be a part of the micro light-emitting chip 1A and may be located in the area (e.g., space S) between the first sub-chip 100A and the second sub-chip 100B. Here, the insulating structure 130 may use, for example, ion implantation technology to change the characteristics of the first semiconductor layer 101, so that it loses semiconductor conductivity. Specifically, ions may be implanted to cause defects or irregularities in the crystal lattice of the first semiconductor layer 101 to trap or hinder carriers from passing through the insulating structure 130, thereby reducing the conductivity in the area. In addition, mechanical stress, for example, may also be applied to change the energy band structure, so as to reduce the semiconductor characteristics of the insulating structure 130, and the above methods may be used alone or in combination. However, the disclosure is not limited thereto. In some embodiments, the material of the insulating structure 130 may be different from the material of the first semiconductor layer 101. The insulating structure 130 may be connected between the first semiconductor layer 101 of the first sub-chip 100A and the second sub-chip 100B to have a first contact surface TS1 and a second contact surface TS2 respectively. That is to say, the parts of the two sub-chips respectively adjacent to the insulating structure 130 are single electrical semiconductors (for example, the first contact surface TS1 contacts the first semiconductor layer 101 of the first sub-chip 100A but does not contact the second semiconductor layer 102 of the first sub-chip 100A). In the embodiment, the parts of the two sub-chips respectively adjacent to the insulating structure 130 have the same electrical properties (for example, both are N-type semiconductors or both are P-type semiconductors). In addition, the space between the first contact surface TS1 and the second contact surface TS2 may define a space S, and the insulating structure 130 fills a part of the space S. The insulating structure 130 may be of, for example, an inorganic insulating material or an organic insulating material, and the disclosure is not limited thereto. In other embodiments not shown, the insulating structure 130 may also completely fill the space S; that is to say, the insulating structure 130 may completely cover the first contact surface TS1 and the second contact surface TS2 and be flush with the upper surface 101S of the first semiconductor layer 101.

In addition, in some embodiments, both the first sub-chip 100A and the second sub-chip 100B may include a passivation layer (silicon oxide) located on the contact surface connected to the insulating structure 130. That is to say, the first contact surface TS1 and the second contact surface TS2 may refer to the parts where the respective passivation layers of the first sub-chip 100A and the second sub-chip 100B are in contact with the insulating structure 130.

With the insulating structure 130 disposed between the first sub-chip 100A and the second sub-chip 100B in the connection direction (direction X in the figure), it may provide sufficient structural strength of the micro light-emitting chip 1A, and further enable the first conductive element 180A to stably connect the first sub-chip 100A and the second sub-chip 100B, thereby enhancing the product reliability of the micro light-emitting chip 1A. Besides, through the structure of the first conductive element 180A connecting the sub-chips in series, the accuracy or uniformity requirements of the micro light-emitting chip 1A may be reduced when bonding, picking up, and transposing to other substrates, and at the same time, damage or breakage is less likely to occur due to the influence of uniformity (such as flatness), which effectively improves the transfer yield of the micro light-emitting chip equipped with the micro light-emitting chip 1A, and also improves the device reliability of the display panel disposed with the micro light-emitting chip 1A.

It is worth mentioning that the distance between the first contact surface TS1 and the second contact surface TS2 may change along the thickness direction of the insulating structure 130 (e.g., the direction Y). For example, the first contact surface TS1 and the second contact surface TS2 have a distance d1 on the side adjacent to the first electrode 121 or the second electrode 122, which gradually increases to a distance d2 toward the side away from the first electrode 121 or the second electrode 122. In some embodiments, the relationship between the distance d1 and the distance d2 may be 1.5d1≤d2≤3d1. Here, the width of the first sub-chip 100A or the second sub-chip 100B (for example, the maximum width of the first semiconductor layer 101 in the direction X) is greater than the distance d2 of the insulating structure 130, for example, 10 times or less the distance d2, so as to ensure that the insulating structure 130 may provide sufficient connection strength. In some implementations, the distance d1 may be 1.5 microns and the distance d2 may be 2.8 microns. In addition, the side of the insulating structure 130 adjacent to the upper surface 101S may have a concave surface facing the negative Y direction, which may further improve the light extraction effect of the micro light-emitting chip 1A.

In addition, the protection element 160 may be an insulating layer composed of an insulating material. For example, the material of the protection element 160 may include inorganic substances such as silicon oxide (SiₓO_{y}) or titanium dioxide (TiO₂), or a coating layer composed of a single material, but is not limited thereto. The protection element 160 may also be a structure with reflective function such as DBR. In detail, in the embodiment, the protection element 160 is disposed on the outer surfaces of the first sub-chip 100A, the second sub-chip 100B, and the insulating structure 130, and has a first surface 161 and a second surface 162 opposite to each other in the direction Y, and the first sub-chip 100A, the second sub-chip 100B, and the insulating structure 130 are located between the first surface 161 and the second surface 162. The first surface 161 and the second surface 162 of the protection element 160 may partially cover or completely cover the outer surfaces or the upper surface 101S of the first sub-chip 100A, the second sub-chip 100B, and the insulating structure 130. Furthermore, in addition to the first surface 161 and the second surface 162, the protection element 160 may also extend to cover the side walls of the micro light-emitting chip 1A (i.e., the peripheral surface in the X direction). In other words, the first sub-chip 100A, the second sub-chip 100B, the insulating structure 130, and the first conductive element 180A may all be integrated in the protection element 160. In this way, the protection element 160 may not only prevent water vapor, oxygen, or other impurities from invading the first sub-chip 100A and the second sub-chip 100B, but also further enhance the structural strength of the micro light-emitting chip 1A, thereby improving the device reliability of the micro light-emitting chip 1A.

In some embodiments, the protection element 160 and the insulating structure 130 may be integrally formed and may be of the same material. That is to say, the insulating structure 130 may also be further flush with the first surface 161 of the protection element 160. It should be noted that since the protection element 160 and the insulating structure 130 become the same structure, especially in the embodiment where the insulating structure 130 is not a part of the micro light-emitting chip 1A, the protection element 160 may perform a supporting function equal to a beam structure on a side of the first surface 161. Specifically, without affecting the light-emitting performance of the upper surface 101S, by appropriately increasing the thickness of the protection element 160 on the first surface 161 (for example, 1.5 to 3 microns), it may directly provide the supporting force of the first sub-chip 100A and the second sub-chip 100B in the Y direction. Thereby, during the chip transfer process, the protection element 160 may produce an effect similar to that of a temporary carrier, giving the entire micro light-emitting chip 1A sufficient mechanical strength. In some embodiments, the protection element 160 and the insulating structure 130 may be manufactured in the same process. However, the disclosure is not limited thereto. In some embodiments, the protection element 160 and the insulating structure 130 may be made of different materials.

In addition, in the embodiment, each of the first sub-chip 100A and the second sub-chip 100B may further include a first contact layer 111 and a second contact layer 112. The first contact layer 111 is disposed between the first semiconductor layer 101 and the first electrode 121, and the second contact layer 112 is disposed on the second semiconductor layer 102. The first contact layer 111 and the second contact layer 112 are, for example, N-type or P-type semiconductor material layers with high doping concentration, or other suitable materials, so as to facilitate the ohmic contact between each of the first conductive element 180A, the first electrode 121, the second electrode 122, the first semiconductor layer 101, and the second semiconductor layer 102. However, the disclosure is not limited thereto. In some embodiments, the first sub-chip 100A and the second sub-chip 100B may not be disposed with the first contact layer 111 and the second contact layer 112.

On the other hand, the micro light-emitting chip 1A may further include a Bragg reflection layer 140. The Bragg reflection layer 140 may extend in the direction X and cover the same side of the first sub-chip 100A and the second sub-chip 100B at the same time, and in the direction Y, the Bragg reflection layer 140 is disposed between the first sub-chip 100A and the first electrode 121, and disposed between the second sub-chip 100B and the second electrode 122. The Bragg reflection layer 140 may have functions of insulation and of reflecting light beams. The aforementioned first conductive element 180A may be electrically connected to the second semiconductor layer 102 of the first sub-chip 100A and the first semiconductor layer 101 of the second sub-chip 100B respectively via a through hole TH12 and a through hole TH21 passing through the Bragg reflection layer 140. Structurally speaking, the Bragg reflection layer 140 may include a plurality of sub-layers, and two adjacent sub-layers may have different dielectric coefficients therebetween. In some embodiments, available materials for the sub-layer of the Bragg reflection layer 140 include aluminum oxide (Al₂O₃), silicon oxide (SiOₓ), silicon nitride (SiN), etc., but are not limited thereto. The dielectric coefficient of the above materials may be further adjusted through specific processes. In some embodiments, the thickness of each of the plurality of sub-layers of the Bragg reflection layer 140 may fall within the wavelength range of visible light, such as 400 nanometers (nm) to 700 nanometers (nm).

On the other hand, in the embodiment, the micro light-emitting chip 1A may also include a transparent conductive layer 170. The transparent conductive layer 170 may be used as a current diffusion layer to cover the second contact layer 112 of the first sub-chip 100A and be disposed between the second semiconductor layer 102 and the first conductive element 180A, and also cover the second contact layer 112 of the second sub-chip 100B and be disposed between the second semiconductor layer 102 and the second electrode 122. The transparent conductive layer 170 may include a transparent conductive material such as indium tin oxide (ITO), indium zinc oxide (IZO), aluminum zinc oxide (AZO), cadmium tin oxide, tin (SnO₂), zinc oxide (ZnO), or any other transparent conductive materials, but not limited thereto.

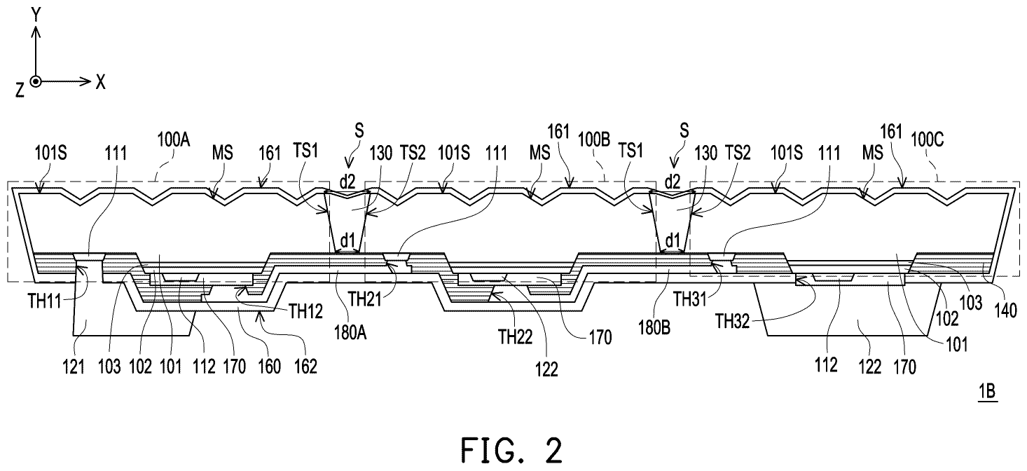

FIG. 2 is a schematic cross-sectional view of a micro light-emitting chip according to an embodiment of the disclosure. Referring to FIG. 2, a micro light-emitting chip 1B of the embodiment is similar to the micro light-emitting chip 1A. The main difference thereof lies in the number of serially connected sub-chips. In detail, the micro light-emitting chip 1B also includes a third sub-chip 100C and a second conductive element 180B, and the protection element 160 further covers the third sub-chip 100C and the second conductive element 180B. The second sub-chip 100B and the third sub-chip 100C may also have an insulating structure 130 therebetween, which has the first contact surface TS1 and the second contact surface TS2 with the second sub-chip 100B and the third sub-chip 100C respectively. Or as mentioned above, the insulating structure 130 may be made from the space S between the second sub-chip 100B and the third sub-chip 100C by using ion implantation technology or the like to change the characteristics of the first semiconductor layer 101. The second conductive element 180B is electrically connected to the second sub-chip 100B and the third sub-chip 100C. In other words, the micro light-emitting chip 1B is composed of three sub-chips connected in series with each other. Furthermore, the second electrode 122 is connected to the transparent conductive layer 170, and then is instead electrically connected to the second semiconductor layer 102 of the third sub-chip 100C via a through hole TH32 penetrating through the protection element 160 and the Bragg reflection layer 140.

In the embodiment, the second conductive element 180B may have the same material as the first conductive element 180A. The third sub-chip 100C may have the same structure and composition as the first sub-chip 100A or the second sub-chip 100B, but the disclosure is not limited thereto. On the other hand, the second conductive element 180B may be electrically connected to the second semiconductor layer 102 of the second sub-chip 100B and the first semiconductor layer 101 of the third sub-chip 100C respectively via the through hole TH22 and a through hole TH31 that penetrate through the Bragg reflection layer 140. In other embodiments, the number of sub-chips may be 3 or more than 3 (for example, 4 or 5), and the number of conductive elements and the number of insulating structures 130 between two adjacent sub-chips may be increased accordingly. For example, when the number of sub-chips is n, the number of conductive elements and insulating structures 130 may be n−1, and the disclosure is not limited thereto.

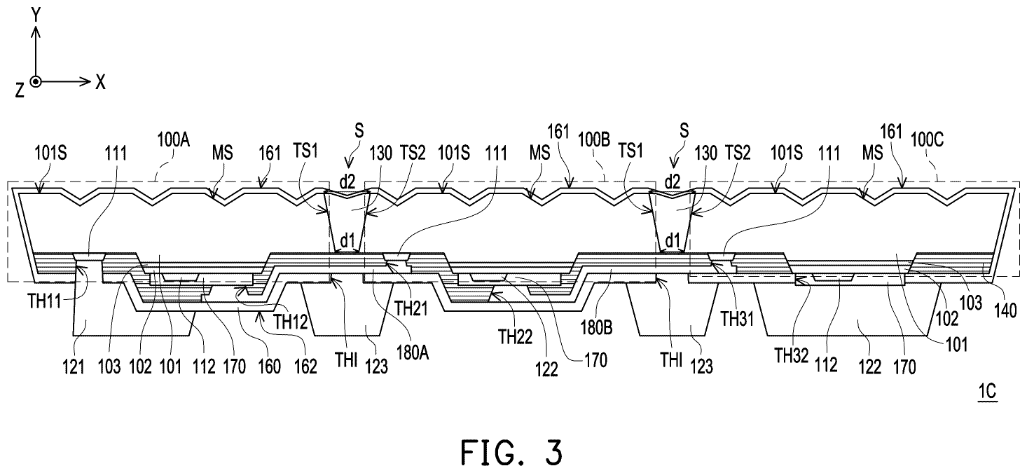

FIG. 3 is a schematic cross-sectional view of a micro light-emitting chip according to an embodiment of the disclosure. Referring to FIG. 3, a micro light-emitting chip 1C of the embodiment is similar to the micro light-emitting chip 1B. The main difference thereof lies in that the micro light-emitting chip 1C also includes an intermediate electrode 123, which is electrically connected to the first conductive element 180A and/or electrically connected to the second conductive element 180B.

Specifically, the intermediate electrode 123 may have the same material as the first electrode 121 or the second electrode 122. The number of intermediate electrodes 123 may be the same as the number of corresponding conductive elements (for example, two in the embodiment), and they are electrically connected to the first conductive element 180A and the second conductive element 180B respectively via two through holes THI that penetrate through the protection element 160. The intermediate electrode 123 may be applied with corresponding voltages to regulate the current of individual sub-chips in the micro light-emitting chip 1C, so as to adjust the brightness or switching of the first sub-chip 100A, the second sub-chip 100B and the third sub-chip 100C. For example, the potential difference between the first electrode 121 and one of the two intermediate electrodes 123 may be increased, thereby increasing the brightness of the first sub-chip 100A and/or the second sub-chip 100B. It is worth mentioning that in the cross-sectional view of FIG. 3, the first electrode 121, the second electrode 122, and the two intermediate electrodes 123 are respectively located on the same cross-section. However, the disclosure is not limited thereto. In other embodiments not shown, the first electrode 121, the second electrode 122, and the two intermediate electrodes 123 may not be located on the same cross-section.

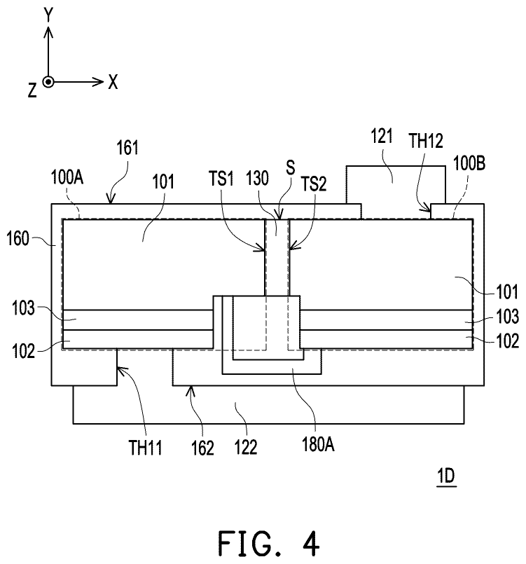

FIG. 4 is a schematic cross-sectional view of a micro light-emitting chip according to an embodiment of the disclosure and a modified embodiment thereof. The difference from FIG. 1 to FIG. 3 is that for clarity of illustration, some components in the embodiments described here and later are not drawn according to true proportions or true shapes. Referring to FIG. 4, a micro light-emitting chip 1D of the embodiment is similar to the micro light-emitting chip 1A. The main difference thereof lies in the different design methods of the electrodes. In detail, the first electrode 121 and the second electrode 122 of the micro light-emitting chip 1D may be respectively disposed on two opposite sides of the micro light-emitting chip 1D. For example, the first electrode 121 may be disposed on the first surface 161 of the protection element 160 and may be electrically connected to the first semiconductor layer 101 of the second sub-chip 100B via the through hole TH12 penetrating through the protection element 160. Correspondingly, the second electrode 122 may be disposed on the second surface 162 of the protection element 160 and may be electrically connected to the second semiconductor layer 102 of the first sub-chip 100A via the through hole TH11 penetrating through the protection element 160. In other words, the entire micro light-emitting chip 1D may be regarded as a vertical light-emitting diode (vertical LED).

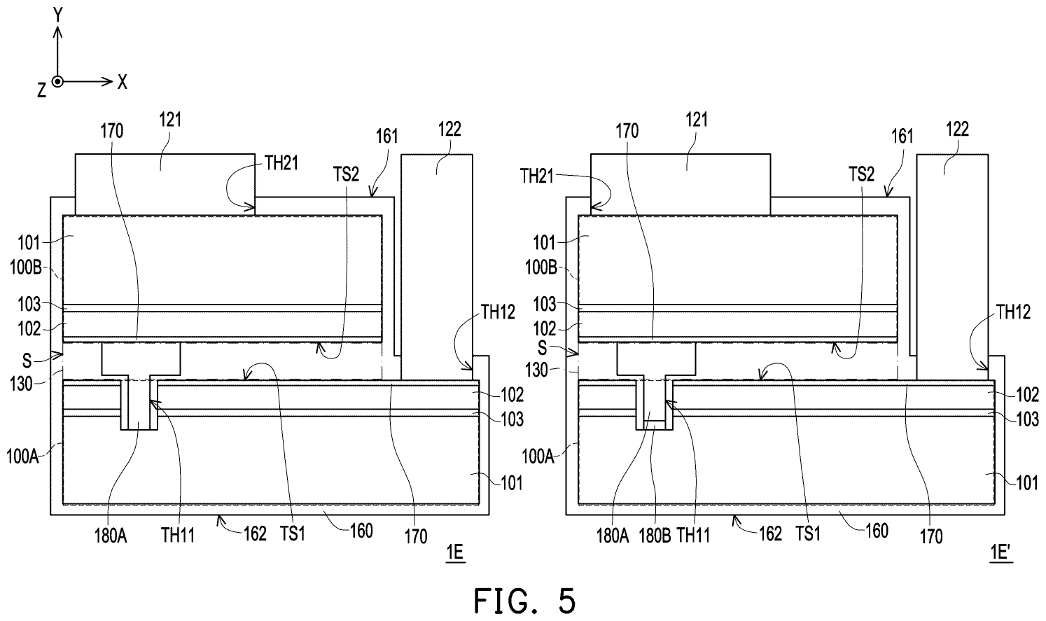

FIG. 5 is a schematic cross-sectional view of a micro light-emitting chip according to an embodiment of the disclosure and a modified embodiment thereof. Referring to FIG. 5, a micro light-emitting chip 1E of the embodiment and a micro light-emitting chip 1E′ of a modified embodiment thereof are similar to the micro light-emitting chip 1D. The main difference thereof lies in the stacking method of the sub-chips. In detail, in the micro light-emitting chip 1E and the micro light-emitting chip 1E′, each of the first sub-chip 100A and the second sub-chip 100B at least partially overlap in the thickness direction.

In detail, in the embodiment, the first sub-chip 100A may be regarded as a flip-chip type light-emitting diode, which uses the first conductive element 180A located on the same side of the first sub-chip 100A and the second electrode 122 that passes through the through hole TH12 to be electrically connected to the first semiconductor layer 101 and the second semiconductor layer 102 respectively. On the contrary, the second sub-chip 100B may be regarded as a vertical light-emitting diode, which uses the first electrode 121 and the first conductive element 180A located on two opposite sides of the second sub-chip 100B to be electrically connected to the first semiconductor layer 101 and the second semiconductor layer 102 respectively. Furthermore, one end of the first conductive element 180A may electrically contact the transparent conductive layer 170 of the second sub-chip 100B, and the other end may electrically contact the first semiconductor layer 101 of the first sub-chip 100A via the through hole TH11. Accordingly, the first sub-chip 100A and the second sub-chip 100B are connected in series, and the first electrode 121 and the second electrode 122 of the micro light-emitting chip 1E are both disposed on the same side, so the entirety may be regarded as a flip-chip type light-emitting diode.

On the other hand, the micro light-emitting chip 1E′ is similar to the micro light-emitting chip 1E. The difference is that the first conductive element 180A in the micro light-emitting chip 1E may be made of different materials (such as metal) from the transparent conductive layer 170, and the micro light-emitting chip 1E′ has the first conductive element 180A and the second conductive element 180B. The first conductive element 180A is the same material extending from the transparent conductive layer 170, while the second conductive element 180B is a metal material to facilitate ohmic contact with the first semiconductor layer 101 of the first sub-chip 100A.

By disposing the through hole TH11 on the thin second semiconductor layer 102 in the first sub-chip 100A (for example, in FIG. 5, the second semiconductor layer 102 of the first sub-chip 100A may be a P-type semiconductor layer, and the first semiconductor layer 101 may be an N-type semiconductor layer), the pattern exposure depth required for the through hole TH11 may be shortened to avoid leakage problems caused by poor exposure. On the other hand, the current may also conduct the first semiconductor layer 101 of the first sub-chip 100A and the second semiconductor layer 102 of the second sub-chip 100B via the shorter first conductive element 180A (i.e., the length in the Y direction). In this way, in addition to being easier to manufacture and effectively improving chip lifetime and yield, the first conductive element 180A may also reduce resistance in terms of electrical effects, thereby achieving better light-emitting efficiency and reducing heat generation.

Corresponding to the aforementioned example, in the embodiment, the protection element 160 and the insulating structure 130 are of the same material. Specifically, the insulating structure 130 may be a protection element 160 disposed in the space S between the first sub-chip 100A and the second sub-chip 100B in the direction Y. That is to say, in the micro light-emitting chip 1E and the micro light-emitting chip 1E′, the first conductive element 180A is disposed in the insulating structure 130 and integrated in the protection element 160 together with the first sub-chip 100A and the second sub-chip 100B.

It should be noted that in the cross-sectional view of the micro light-emitting chip 1E and the micro light-emitting chip 1E′ of FIG. 5, it is shown that the first sub-chip 100A and the second sub-chip 100B are completely overlapped. However, in the direction parallel to a direction Z, the sizes of the first sub-chip 100A and the second sub-chip 100B may have differences. It may also be understood that at least a part of the projection of the first sub-chip 100A in the direction Y does not overlap the second sub-chip 100B. Therefore, the intermediate electrode 123 (not shown in FIG. 5) in the aforementioned embodiment may also be disposed in the non-overlapping part of the two sub-chips and may be electrically connected to the first conductive element 180A via the internal connection conductive structure in the direction Z to achieve the aforementioned electrical control function of the intermediate electrode 123. Of course, the disclosure is not limited thereto.

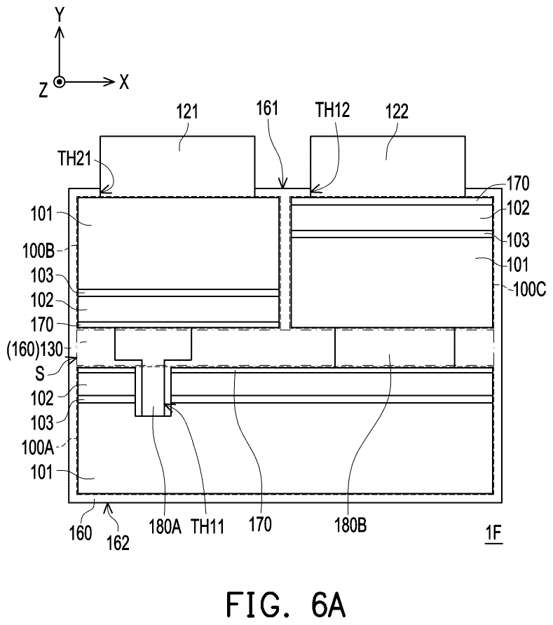

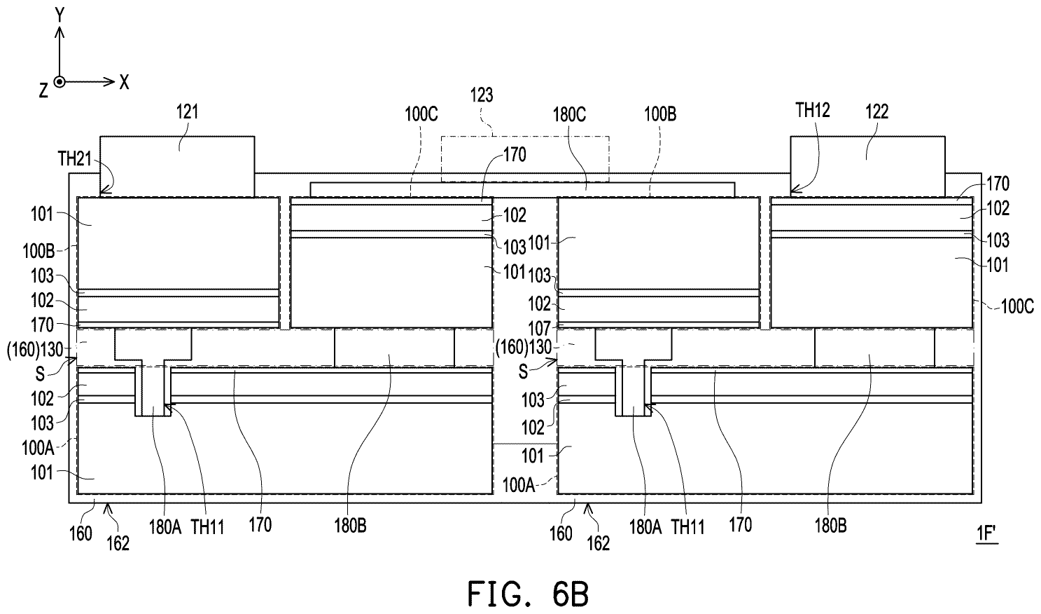

FIG. 6A is a schematic cross-sectional view of a micro light-emitting chip according to an embodiment of the disclosure. Referring to FIG. 6A, a micro light-emitting chip 1F of the embodiment is similar to the micro light-emitting chip 1E. The main difference thereof lies in that the micro light-emitting chip 1F also includes the third sub-chip 100C and the second conductive element 180B, and the second conductive element 180B is substantially a conductive layer with a planar structure.

Specifically, in the embodiment, the micro light-emitting chip 1F may include the first sub-chip 100A of a flip-chip type light-emitting diode, two second sub-chips 100B of vertical light-emitting diodes, and the third sub-chip 100C, the first conductive element 180A, and the second conductive element 180B. The first conductive element 180A is electrically connected to the first semiconductor layer 101 of the first sub-chip 100A via the through hole TH11, and the other end is connected to the second semiconductor layer 102 of the second sub-chip 100B via the transparent conductive layer 170. The second conductive element 180B is disposed on the transparent conductive layer 170 of the first sub-chip 100A, and the other end is connected to the first semiconductor layer 101 of the third sub-chip 100C. In addition, the micro light-emitting chip 1F further includes the first electrode 121 and the second electrode 122. The first electrode 121 is disposed on the first semiconductor layer 101 of the second sub-chip 100B via the through hole TH21, and the second electrode 122 is disposed on the transparent conductive layer 170 of the third sub-chip 100C via the through hole TH12. When the micro light-emitting chip 1F is enabled, the first electrode 121 and the second electrode 122 may be applied with a potential difference. The current may be transmitted to the second electrode 122 through the first electrode 121, the second sub-chip 100B, the first conductive element 180A, the first sub-chip 100A, the second conductive element 180B, and the third sub-chip 100C in sequence. Accordingly, the micro light-emitting chip 1F may realize three sub-chips connected in series, and due to the configuration relationship of the first sub-chip 100A, the second sub-chip 100B, and the third sub-chip 100C, the micro light-emitting chip 1F may be regarded as a flip-chip type light-emitting chip that may be directly bonded onto the circuit substrate.

It is worth mentioning that a plurality of micro light-emitting chips 1F may be connected in series with each other. FIG. 6B is a schematic cross-sectional view of a micro light-emitting chip according to an embodiment of the disclosure. For example, FIG. 6B illustrates a micro light-emitting chip 1F′, which is a series-connected structure formed by respectively removing one of the first electrode 121 and the second electrode 122 of the two micro light-emitting chips 1F and connecting a third conductive element 180C to the second semiconductor layer 102 of the third sub-chip 100C of the micro light-emitting chip 1F and to the first semiconductor layer 101 of the second sub-chip 100B of another micro light-emitting chip 1F. In addition, the two micro light-emitting chips 1F may be covered by the protection element 160 or integrated into one body to ensure the overall structural strength and device reliability. On the other hand, the first electrode 121 and the second electrode 122 retained in the micro light-emitting chip 1F′ serve as contacts for the outer joining circuit. In addition, the third conductive element 180C may be made of the same material as the first conductive element 180A or the second conductive element 180B, and the disclosure is not limited thereto. In some embodiments, the intermediate electrode 123 of the aforementioned embodiment may also be further disposed on the third conductive element 180C (for example, represented by a dotted line in FIG. 6B) to achieve the aforementioned electrical control function and serve as an additional support point for the micro light-emitting chip 1F.

In more embodiments not shown, the micro light-emitting chip 1F′ may also include a plurality of third conductive elements 180C. That is to say, since the entire micro light-emitting chip 1F is a flip-chip type structure, the series-connected positions between a plurality of chips are located on the same side (for example, the first surface 161 of FIG. 6A) and therefore they may be connected in series by disposing the plurality of third conductive elements 180C.

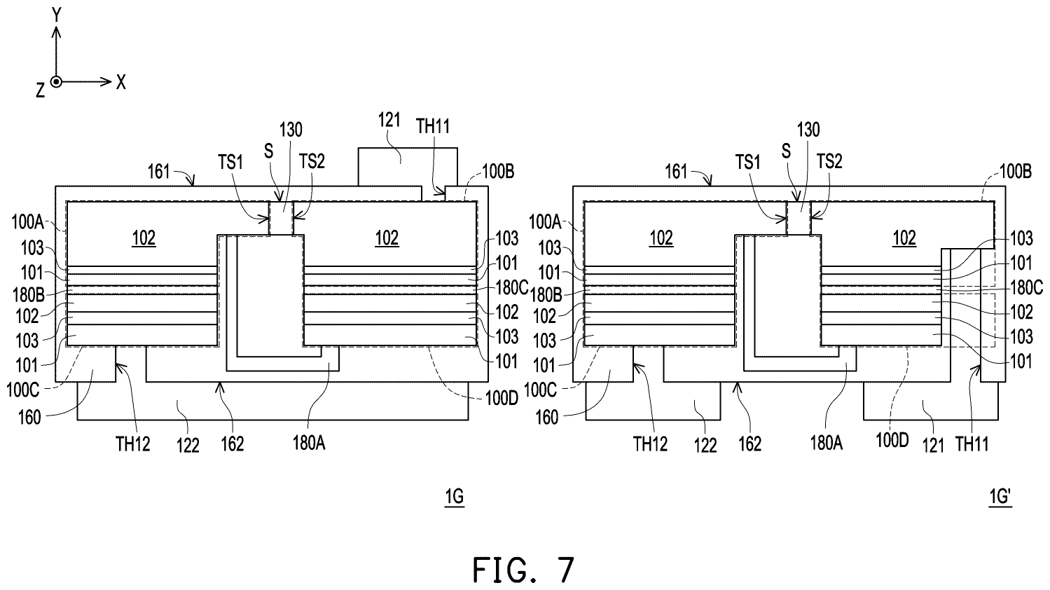

FIG. 7 is a schematic cross-sectional view of a micro light-emitting chip according to an embodiment of the disclosure and a modified embodiment thereof. Referring to FIG. 7, a micro light-emitting chip 1G of the embodiment and a micro light-emitting chip 1G′ of a modified embodiment thereof are similar to the micro light-emitting chip 1D and the micro light-emitting chip 1D respectively. The main difference thereof lies in that the number of sub-chips and the number of conductive elements are different. For example, the micro light-emitting chip 1G also includes the third sub-chip 100C and a fourth sub-chip 100D.

Specifically, the second semiconductor layer 102 of the third sub-chip 100C is electrically connected to the first semiconductor layer 101 of the first sub-chip 100A via the second conductive element 180B; the second semiconductor layer 102 of the fourth sub-chip 100D is electrically connected to the first semiconductor layer 101 of the second sub-chip 100B via the third conductive element 180C; and the second semiconductor layer 102 of the first sub-chip 100A may be connected to the second semiconductor layer 102 of the second sub-chip 100B via the insulating structure 130. In addition, two ends of the first conductive element 180A may be respectively connected to the second semiconductor layer 102 of the first sub-chip 100A and the first semiconductor layer 101 of the fourth sub-chip 100D.

In the micro light-emitting chip 1G and the micro light-emitting chip 1G′, the first electrode 121 and the second electrode 122 are electrically connected to the second semiconductor layer 102 of the second sub-chip 100B and the first semiconductor layer 101 of the third sub-chip 100C via the through hole TH11 and the through hole TH12 respectively. The difference is that the first electrode 121 and the second electrode 122 of the micro light-emitting chip 1G are respectively disposed on the first surface 161 and the second surface 162 on the opposite sides of the protection element 160, while in the micro light-emitting chip 1G′ of the modified embodiment, both the first electrode 121 and the second electrode 122 are disposed on the second surface 162.

Therefore, each sub-chip is electrically connected via the second conductive element 180B and the third conductive element 180C in the direction Y, each sub-chip is electrically connected via the first conductive element 180A in the direction X, and the micro light-emitting chip 1G and the micro light-emitting chip 1G′ may realize the series connection of the four sub-chips and may be regarded as a multi-junction micro light-emitting diode chip.

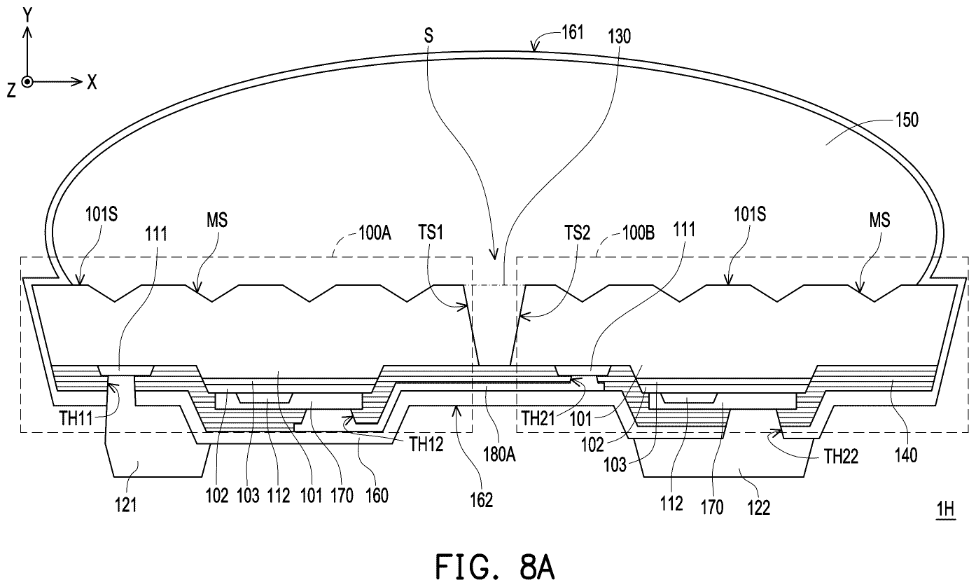

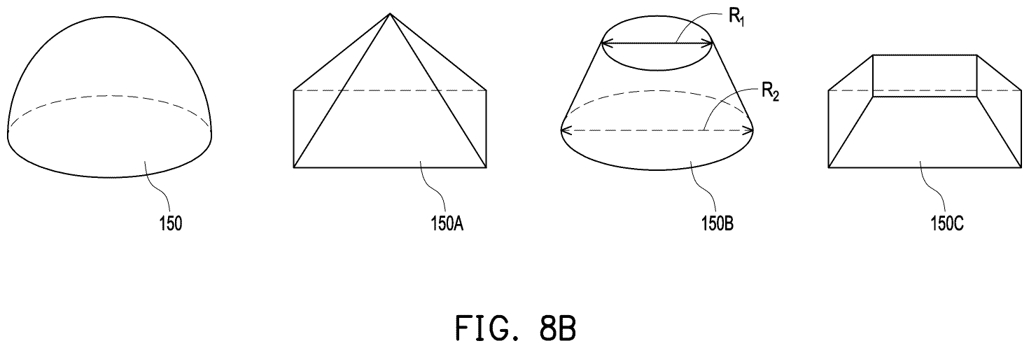

FIG. 8A is a schematic cross-sectional view of a micro light-emitting chip according to an embodiment of the disclosure. Referring to FIG. 8A, a micro light-emitting chip 1H of the embodiment is similar to the micro light-emitting chip 1A. The main difference thereof lies in that the micro light-emitting chip 1H also includes an optical structure 150 disposed on a side of the micro light-emitting chip 1H, for example, directly covering the upper surface 101S and covering the microstructure MS. The insulating structure 130 is disposed on the same side, and the insulating structure 130 and the optical structure 150 are integrally formed. That is to say, in the embodiment, the material of the optical structure 150 may be further filled into the space S and may further contact the first contact surface TS1 and the second contact surface TS2 to form the aforementioned insulating structure 130. In other embodiments not shown, the upper surface 101S may be a flat surface, that is, without the microstructure MS.

The optical structure 150 may at least partially overlap or completely overlap the light-emitting layers 103 of both the first sub-chip 100A and the second sub-chip 100B in the direction Y. The optical structure 150 is used to converge the light beams emitted by the two light-emitting layers 103 to increase the proportion of forward light output (such as direction Y) of the micro light-emitting chip 1H, so as to effectively increase the brightness and improve the situation where color mixing easily occurs and causes color shift when a plurality of micro light-emitting chips 1H are used as pixels in a display device, thereby improving the picture quality. The microlens array in which a plurality of optical structures 150 are arranged may be designed according to the required field of view distribution and light uniformity, and may have different arrangements and densities.

It is worth mentioning that the optical structure 150 may be of inorganic insulating material, organic insulating material, or the same material as the aforementioned insulating structure 130, and the disclosure is not limited thereto. In addition, the first surface 161 of the protection element 160 may completely cover the entire outer surface of the optical structure 150. In other words, the optical structure 150 may be integrated into the protection element 160 together with the first sub-chip 100A, the second sub-chip 100B, the insulating structure 130, and the first conductive element 180A.

FIG. 8B is a schematic structural view of different embodiments of the optical structure of FIG. 8A. Referring to FIG. 8B, the optical structure may have different implementation aspects. For example, in the stereoscopic view, the optical structure may be a semicircular or semielliptical optical structure 150, a quadrangular pyramid optical structure 150A, or a frustoconical optical structure 150B with a larger bottom radius R2 and a smaller top radius R1, and a truncated pyramid optical structure 150C, the disclosure does not limit the type or shape of the optical structure.

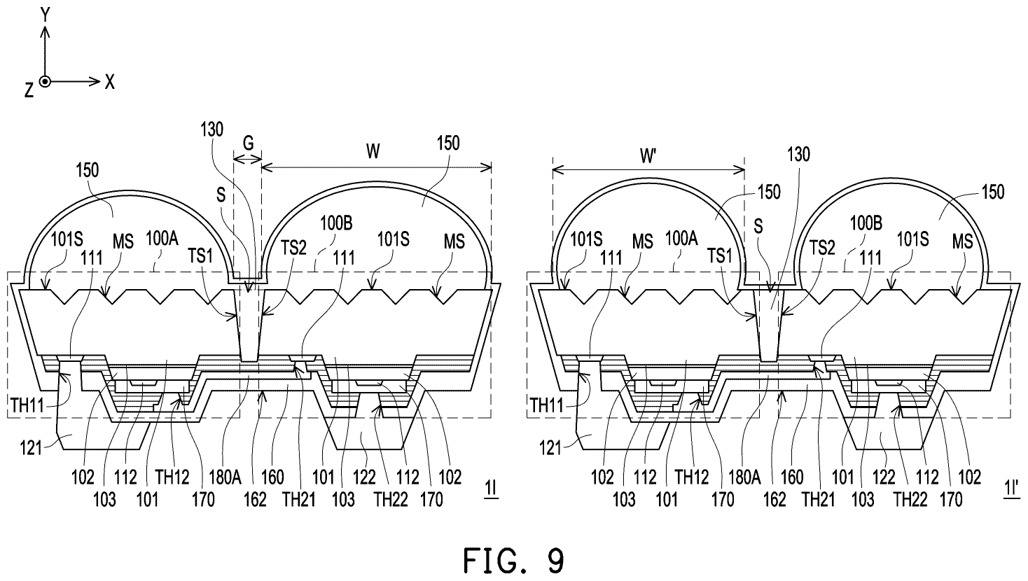

FIG. 9 is a schematic cross-sectional view of a micro light-emitting chip according to an embodiment of the disclosure and a modified embodiment thereof. Referring to FIG. 9, a micro light-emitting chip 1I of the embodiment and a micro light-emitting chip 1I′ of a modified embodiment thereof are similar to the micro light-emitting chip 1H. The main difference thereof lies in the number of optical structures 150. In detail, each of the micro light-emitting chip 1I and the micro light-emitting chip 1I′ includes two optical structures 150 overlapping the light-emitting layer 103 of the first sub-chip 100A and overlapping the light-emitting layer 103 of the second sub-chip 100B respectively. Furthermore, in the micro light-emitting chip 1I, the two optical structures 150 and the insulating structure 130 in the space S may be integrally formed of the same insulating material, or each of the optical structure 150 and the insulating structure 130 may be made of different materials. In the micro light-emitting chip 1I′, the two optical structures 150 and the insulating structure 130 in the space S may be separated from each other and further separated by the protection element 160.

In some embodiments, in the direction Y, the ratio of the projected area of the optical structure 150 to the projected area of the upper surface 101S may be greater than or equal to 0.8 and less than or equal to 1.2. In some embodiments, a maximum width W (or width W′) of the optical structure 150 in the direction X may be greater than or equal to 1 micron and less than or equal to 5 microns. Furthermore, in some embodiments, a distance G between the two optical structures 150 may be less than or equal to 5 microns.

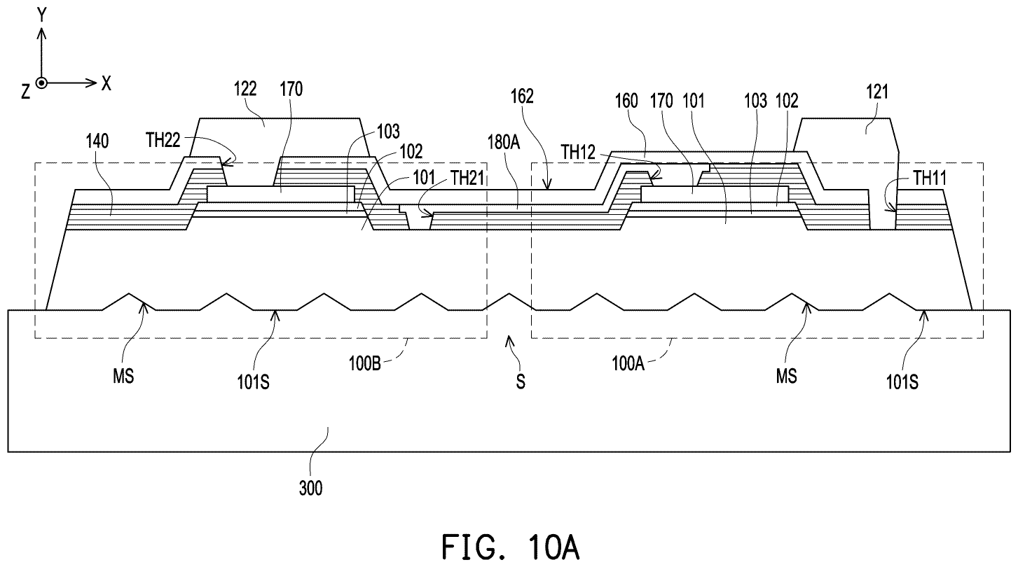

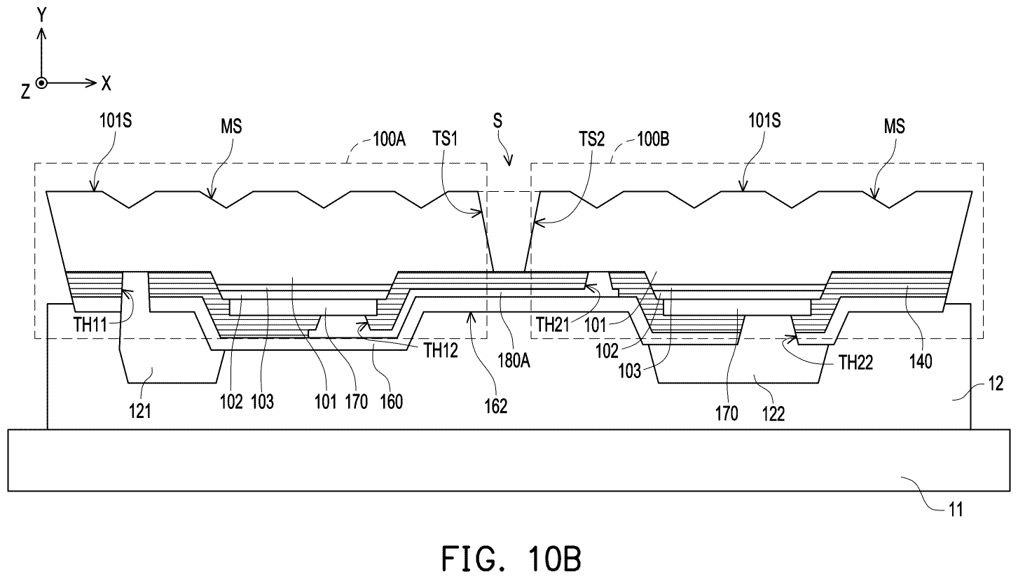

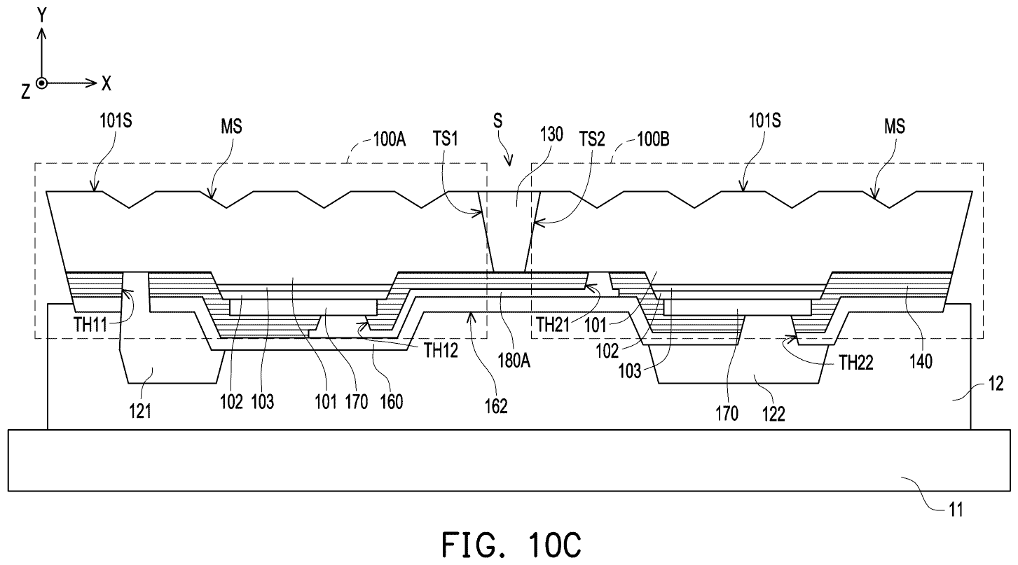

FIG. 10A to FIG. 10C are schematic views of a manufacturing process of a micro light-emitting chip according to an embodiment of the disclosure. Referring to FIG. 10A first, in the process stage (Chip on Wafer, COW) on a patterned growth substrate 300, the patterned first semiconductor layer 101, the light-emitting layer 103, the second semiconductor layer 102, the transparent conductive layer 170, and the Bragg reflection layer 140 may be sequentially generated on the patterned growth substrate 300. The through hole TH12 and the through hole TH21 are formed on the Bragg reflection layer 140 via an etching process, so that the subsequently generated first conductive element 180A may be electrically connected to the transparent conductive layer 170 located in the first sub-chip 100A area and the first semiconductor layer 101 located in the second sub-chip 100B area respectively via the through hole TH12 and the through hole TH21. Here, the microstructure MS contained in the micro light-emitting chip is grown corresponding to the surface pattern of the patterned growth substrate 300. However, in some embodiments, such as when manufacturing red light micro light-emitting diodes, a general epitaxial substrate may be used instead of the patterned growth substrate 300.

Next, the first conductive element 180A and each of the above film layers or elements are covered by depositing the material of the protection element 160. Then, through the etching process, the through hole TH11 and the through hole TH22 penetrating through the protection element 160 and the Bragg reflection layer 140 are generated, and finally, the first electrode 121 and the second electrode 122 are generated to be electrically connected to the first semiconductor layer 101 of the first sub-chip 100A and the transparent conductive layer 170 of the second sub-chip 100B respectively. The above-mentioned elements or film layers may be manufactured by adopting chemical vapor deposition (CVD) or physical vapor deposition (PVD) to sequentially epitaxially form the thin films, and patterning each epitaxial film to form the outline or pattern of each element using a photolithography process, and the disclosure is not limited thereto. It should be noted that only one manufacturing process of an epitaxial structure is shown in the figure, but in fact, the number of epitaxial structures may be plural.

Referring again to FIG. 10B, a plurality of epitaxial structures are then transferred to a temporary carrier to form a micro light-emitting chip structure. For example, a temporary carrier 11 and a fixing element 12 (such as an electrically insulating colloid) may be provided, and a plurality of epitaxial structures of FIG. 10A are fixed on the temporary carrier 11 via the fixing element 12. The plurality of epitaxial structures are electrically insulated from the temporary carrier 11. The temporary carrier 11 is, for example, a temporary carrier such as a plastic substrate, a glass substrate, or a sapphire substrate, and may be fixed and have a flat surface, but is not limited thereto.

In the process stage (Chip on Carrier, COC) on the temporary carrier 11, the first semiconductor layer 101 is etched to form the space S. Here, since the etching liquid or etching gas etches from above to below, an under cut structure is easily formed below the mask (not shown) covering the first semiconductor layer 101 around the space S. Therefore, the space S has a gradual width in the thickness direction (direction Y), that is, the relationship between the distance d1 and the distance d2 in the aforementioned embodiment or the inverted trapezoidal structure in the cross-sectional view of FIG. 10B. However, the disclosure is not limited thereto. The space S may also be formed by other patterning processes, such as ion beam etching (IBE), or dry etching methods such as reactive ion etching (RIE) and inductively coupled plasma etching (ICP), which will not be described here.

Continuing to refer to FIG. 10C, then, the insulating material may be filled into the space S using the aforementioned PVD or CVD process. The insulating material respectively contacts the first semiconductor layer 101 on both sides in the space S to form the insulating structure 130 between the first contact surface TS1 and the second contact surface TS2.

It should be noted that as mentioned above, ion implantation technology, for example, may also be used to change the characteristics of the space S in the first semiconductor layer 101 so that it loses the conductivity of the semiconductor to form the insulating structure 130. In the embodiment, there is no need to etch the first semiconductor layer 101. For related contents, reference may be made to the foregoing paragraphs and details are not repeated here. In the aforementioned steps of FIG. 10A, since the first conductive element 180A is formed after the Bragg reflection layer 140, in addition to providing optical reflection, the Bragg reflection layer 140 may also serve as an etching stop layer at this stage to protect the first conductive element 180A from being easily degraded or damaged during the manufacturing process so as to ensure the yield of the micro light-emitting chip. In subsequent processes, an insulating material may be continued to be deposited to cover the upper surface 101S and the insulating structure 130 to form a complete protection element 160. Accordingly, the micro light-emitting chip 1A shown in FIG. 1 is preliminarily completed. Of course, the disclosure is not limited thereto. In the embodiments described later, the optical structure 150 of FIG. 8A and the insulating structure 130 filling the space S may be simultaneously produced through a coating process, a deposition process, and a development process to form the micro light-emitting chip 1H.

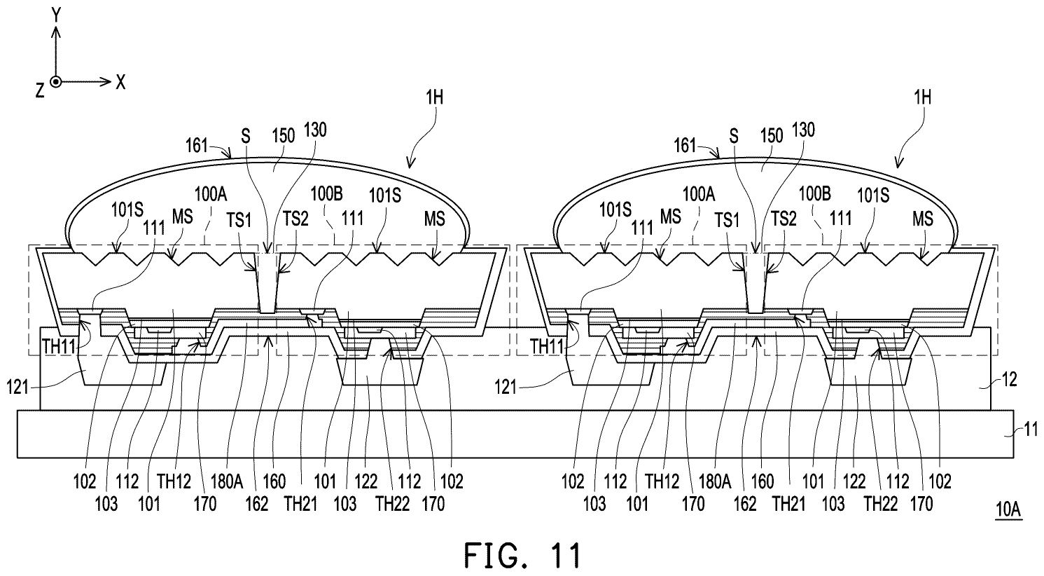

For example, FIG. 11 is a schematic cross-sectional view of a micro light-emitting chip structure according to an embodiment of the disclosure. In FIG. 11, a micro light-emitting chip structure 10A is used to load two micro light-emitting chips 1H as an exemplary illustration. On the other hand, the first electrode 121 (or the second electrode 122) and the insulating structure 130 are respectively located on opposite sides of the micro light-emitting chip 1H, or are respectively located on opposite sides of the first sub-chip 100A (or the second sub-chip 100B). In addition, the first electrode 121 and the second electrode 122 are located between the micro light-emitting chip 1H and the temporary carrier 11. It should be noted that in the figure, the preparation of the micro light-emitting chip 1H is used as an exemplary illustration. However, the micro light-emitting chips in other embodiments mentioned above may also be manufactured using similar methods as described above, and details are not repeated here.

Similarly, each of the micro light-emitting chips of the abovementioned embodiments may also have a loading pattern similar to the micro light-emitting chip structure 10A. For example, the aforementioned micro light-emitting chip 1F may also be disposed on the temporary carrier 11 via the fixing element 12. Accordingly, in the thickness direction of the first sub-chip 100A or the second sub-chip 100B of the micro light-emitting chip 1F, the projection of the first sub-chip 100A or the second sub-chip 100B on the temporary carrier 11 may also completely cover the projection of the first conductive element 180A on the temporary carrier 11. For the micro light-emitting chip structure of each micro light-emitting chip in the abovementioned embodiments, reference may be made to the foregoing paragraphs and details are not repeated here.

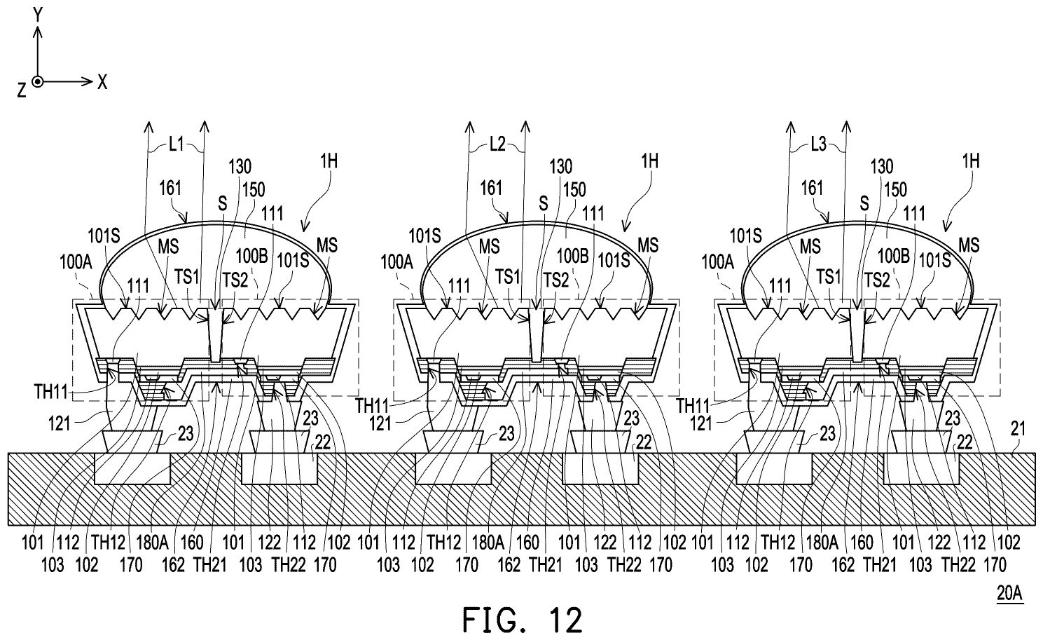

FIG. 12 is a schematic cross-sectional view of a display panel according to an embodiment of the disclosure. Referring to FIG. 12, a display panel 20A includes a circuit substrate 21. The circuit substrate 21 has a plurality of pixel circuits 22 and pads 23 electrically connected to the pixel circuits 22. The plurality of micro light-emitting chips 1H are disposed on the circuit substrate 21 and electrically connected to the pads 23 via the first electrode 121 and the second electrode 122 to complete the electrical connection between the plurality of micro light-emitting chips 1H and the circuit substrate 21. After the aforementioned micro light-emitting chips 1H shown in FIG. 10A to FIG. 10C and FIG. 11 are manufactured, mass transfer technology may be used to pick up the plurality of micro light-emitting chips 1H at the same time and transpose them onto the circuit substrate 21 so as to complete the display panel 20A.

In the embodiment, the circuit substrate 21 includes a variety of signal lines (such as data lines, scanning lines, or power lines, not shown) and pixel circuits 22 connected thereto, which may respectively provide two pads 23 with electrical signals, so that the micro light-emitting chip 1H emits a display light beam. It is worth mentioning that the three micro light-emitting chips 1H shown in FIG. 12 may respectively emit light beams of different wavelength ranges. For example, the three micro light-emitting chips 1H may respectively emit a light beam L1 of red light wavelength, a light beam L2 of green light wavelength, and a light beam L3 of blue light wavelength. Of course, the disclosure is not limited thereto. In other embodiments, the light beams emitted by the plurality of micro light-emitting chips 1H may also have substantially the same wavelength range.

The circuit substrate 21 is, for example, a driving substrate adopting silicon wafer material and including a complementary metal oxide semiconductor (CMOS) to improve the response speed of each switching element in the circuit substrate 21 and reduce the power consumption, so as to meet the demands of fast response and high resolution of the display panel 20A. However, the disclosure is not limited thereto. In other embodiments, the circuit substrate 21 may also be a printed circuit board (PCB) or a transparent display panel. In other embodiments, the circuit substrate 21 may also be a combination of a glass substrate and a pixel circuit layer, where the pixel circuit layer is formed on the glass substrate using a semiconductor process, and the pixel circuit layer may include an active element (such as thin-film transistor) and various signal lines (such as data lines, scanning lines, or power lines, not shown), but not limited thereto.

In the display panel 20A, the first electrode 121, the second electrode 122, and the insulating structure 130 are respectively located on opposite sides of the micro light-emitting chip 1H. Or, for example, in the aforementioned embodiments of the micro light-emitting chip 1D and the micro light-emitting chip 1G, only the second electrode 122 and the insulating structure 130 are located on opposite sides. It should be noted that, since after the COW stage of manufacturing the first electrode 121 and the second electrode 122 is completed, the micro light-emitting chip 1H is first flipped once to form the insulating structure 130, the first electrode 121 and/or the second electrode 122 and the insulating structure 130 will be located on opposite sides of the micro light-emitting chip 1H when being subsequently bonded to the circuit substrate 21.

Following the above, the Bragg reflection layer 140 is also located between the first sub-chip 100A and the second sub-chip 100B and the circuit substrate 21. The insulation and reflection functions of the Bragg reflection layer 140 may be utilized to enhance the electrostatic discharge protection function and also reflect the light beam L1, the light beam L2, and the light beam L3 toward the direction Y (such as the front viewing direction of the display panel 20A), thereby effectively improving the brightness and quality of the image.

Through the above, the display panel 20A adopting the micro light-emitting chip 1H as the display pixel may have the advantages of high brightness, low power consumption, and good structural strength, which may reduce the probability of defective pixels occurring, improve the bonding yield of the transfer process, and further improve the product competitiveness.

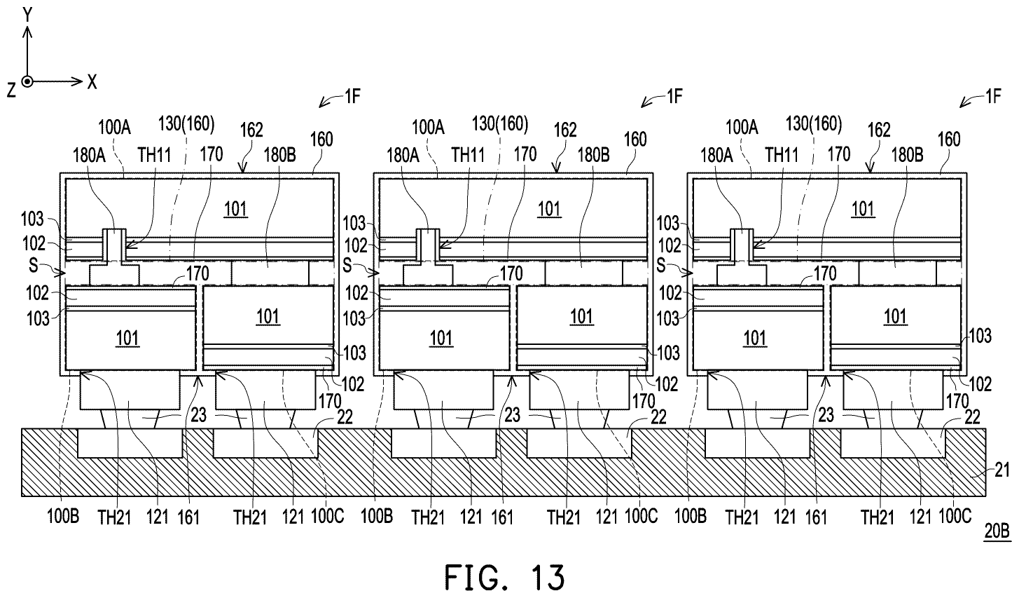

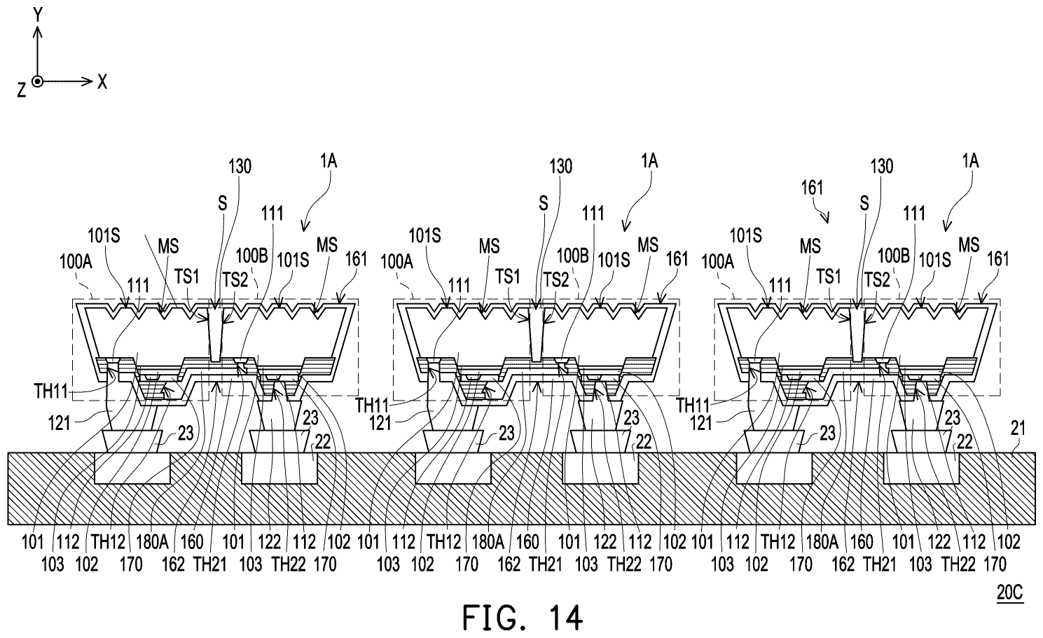

Similarly, a display panel 20B of FIG. 13 and a display panel 20C of FIG. 14 are similar to the display panel 20A of FIG. 12. The difference thereof lies in that the display panel 20B may be equipped with a plurality of micro light-emitting chips 1F as display pixels, and the display panel 20C may be equipped with a plurality of micro light-emitting chips 1A as display pixels. The disclosure is not limited thereto. In the display panel 20B, in the thickness direction of the first sub-chip 100A or the second sub-chip 100B of any micro light-emitting chip 1F, the projection of the first sub-chip 100A or the second sub-chip 100B on the circuit substrate 21 completely covers the projection of the first conductive element 180A on the circuit substrate 21. In other embodiments, the circuit substrate 21 and the pads 23 may also be used to bond the micro light-emitting chips mentioned in the aforementioned embodiments, and details are not repeated here.

To sum up, the micro light-emitting chip of the embodiment of the disclosure includes two or more than two sub-chips, and the plurality of sub-chips form a series-connected structure through the conductive element. In this way, the plurality of sub-chips may share the applied high voltage through the series-connected structure, so that each sub-chip may adjust the appropriate operating voltage accordingly to avoid the power consumption of the step-down circuit and may also have the advantages of the high voltage diode, such as high brightness, high power, and high extraction rate. Not only that, with the insulating structures respectively disposed between two adjacent sub-chips, and the protection elements being disposed on the upper and lower surfaces of the two sub-chips in the thickness direction, the device reliability and structural strength of the micro light-emitting chip may be improved. During the implementation of the transfer process (such as mass transfer), the plurality of micro light-emitting chips on the micro light-emitting chip structure are less likely to be damaged or broken, and may also have a better transfer yield. In addition, display panels that adopt the micro light-emitting chips as display pixels may also have the advantages of high brightness, low power consumption, and good structural strength, further enhancing product competitiveness.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A micro light-emitting chip, comprising:
two sub-chips;
an insulating structure, disposed between the two sub-chips, so that the two sub-chips are electrically insulated from each other at the insulating structure;
a conductive element, electrically connected to the two sub-chips; and
a protection element, wherein the protection element is an insulating layer configured on outer surfaces of the two sub-chips and the insulating structure, the protection element has a first surface and a second surface arranged along a thickness direction of the two sub-chips, and the two sub-chips and the conductive element are located between the first surface and the second surface.

2. The micro light-emitting chip according to claim 1, wherein the insulating structure is of a different material from the two sub-chips and has a contact surface with the two sub-chips respectively, and a distance between the two contact surfaces changes along the thickness direction of the two sub-chips.

3. The micro light-emitting chip according to claim 2, further comprising two electrodes respectively connected to the two sub-chips, wherein the distance gradually increases along a direction away from the two electrodes.

4. The micro light-emitting chip according to claim 1, further comprising two electrodes and an intermediate electrode, wherein the two electrodes are respectively connected to the two sub-chips, and the intermediate electrode is electrically connected to the conductive element.

5. The micro light-emitting chip according to claim 4, wherein the conductive element is disposed in the insulating structure, and the two sub-chips at least partially overlap in the thickness direction thereof.

6. The micro light-emitting chip according to claim 1, wherein parts of the two sub-chips respectively adjacent to the insulating structure are single electrical semiconductors.

7. The micro light-emitting chip according to claim 6, wherein the parts of the two sub-chips respectively adjacent to the insulating structure have a same electrical property.

8. The micro light-emitting chip according to claim 6, further comprising three or more than three sub-chips and two or more than two conductive elements, wherein one of the conductive elements is a conductive layer and is disposed between any two of the sub-chips, and the two conductive elements are connected in series with the sub-chips.

9. The micro light-emitting chip according to claim 1, further comprising an optical structure disposed on a side of the micro light-emitting chip, wherein the insulating structure is disposed on the side, and the insulating structure and the optical structure are integrally formed.

10. The micro light-emitting chip according to claim 1, wherein the two sub-chips and the conductive element are integrated in the protection element.

11. The micro light-emitting chip according to claim 10, wherein the protection element and the insulating structure are of a same material.

12. A micro light-emitting chip structure, comprising:
a temporary carrier;
a fixing element; and
a plurality of micro light-emitting chips, fixed on the temporary carrier through the fixing element, wherein the micro light-emitting chips are electrically insulated from the temporary carrier, and each of the micro light-emitting chips comprises:
two sub-chips;
an insulating structure, disposed between the two sub-chips, so that the two sub-chips are electrically insulated from each other at the insulating structure;
a conductive element, electrically connected to the two sub-chips; and
a protection element, wherein the protection element is an insulating layer configured on outer surfaces of the two sub-chips and the insulating structure, the protection element has a first surface and a second surface arranged along a thickness direction of the two sub-chips, and the two sub-chips and the conductive element are located between the first surface and the second surface.

13. The micro light-emitting chip structure according to claim 12, wherein in a thickness direction of the sub-chip, a projection of the sub-chip on the temporary carrier completely covers a projection of the conductive element on the temporary carrier.

14. The micro light-emitting chip structure according to claim 12, wherein each of the micro light-emitting chips further comprises two electrodes, one of the two electrodes and the insulating structure are respectively located on opposite sides of the micro light-emitting chip, or are respectively located on opposite sides of the sub-chip.

15. The micro light-emitting chip structure according to claim 14, wherein the electrode is located between the micro light-emitting chip and the temporary carrier.

16. A display panel, comprising:
a circuit substrate, disposed with a plurality of pixel circuits; and
a plurality of micro light-emitting chips, disposed on the circuit substrate, wherein each of the micro light-emitting chips comprises:
two sub-chips;
an insulating structure, disposed between the two sub-chips, so that the two sub-chips are electrically insulated from each other at the insulating structure;
a conductive element, electrically connected to the two sub-chips;
two electrodes, electrically connected to one and the other of the two sub-chips respectively, wherein one of the two electrodes is electrically bonded to one of the pixel circuits; and
a protection element, wherein the protection element is an insulating layer configured on outer surfaces of the two sub-chips and the insulating structure, the protection element has a first surface and a second surface arranged along a thickness direction of the two sub-chips, and the two sub-chips and the conductive element are located between the first surface and the second surface.
